(19) United States
(12) Patent Application Publication
(10) Pub. No.: US 2006/0105561 A1
(43) Pub. Date: May 18, 2006

(54) Method of manufacturing a self-aligned contact structure

(76) Inventor: Yunjun Huh, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/986,906

(22) Filed: Nov. 15, 2004

(51) Int. Cl. H01L 21/469

(52) U.S. Cl. 438/618; 438/770

(57) ABSTRACT

The present invention provides a method of manufacturing a self-aligned contact structure comprising a semiconductor substrate having at least two gate stack structures formed thereon. A dielectric layer is formed over the gate stack structures. Each gate stack structure has a nitride layer surface. A portion of the dielectric layer is removed to expose the semiconductor substrate between two gate stack structures and the nitride layer surface, resulting in forming a self-aligned contact. A thermal oxidation is performed on the nitride layer surface to reduce the dielectric constant of the nitride layer surface. After forming the self-aligned contact structure of the present invention, the surrounding oxidized nitride layer surface exhibits a lower parasitic capacitance while operating the devices.

### BACKGROUND OF THE INVENTION

1. Field of the Invention

The present invention relates to a method of manufacturing a contact structure, and more particularly to a method of manufacturing a self-aligned contact structure with lower parasitic capacitance.

2. Description of the Prior Art

The semiconductor industry is continually striving to improve device performance while maintaining, or decreasing, the cost of the semiconductor product. These objects have been partially satisfied by the ability of the industry to create smaller semiconductor devices, thus enabling more semiconductor chips to be realized from a starting substrate, and thereby reducing the processing cost for a specific semiconductor chip. The ability to fabricate devices with sub-micron features has been the main contribution in obtaining smaller chips, with the smaller chips still maintaining levels of integration equal to integration levels achieved by larger chips. The specific semiconductor device processes, for example, the lithography process, and the dry etching process, have become the main key processes for entering the sub-micron process.

In general, the via process is used for the advanced semiconductor process and the particular structure design for the self-aligned contact (SAC), thereby increasing a miniaturized high-speed semiconductor device. A SAC structure process utilizes a contact hole formed between the gate structures. In order to maintain the minimum space between the gate structures, the diameter of this contact hole is less than the diameter provided by the conventional lithography process. In the conventional self-aligned contact process, the gate structure comprises a top layer of silicon nitride layer and silicon nitride spacers on two sidewalls of the gate structure. However, the silicon nitride spacers have a higher dielectric constant, thereby resulting in forming higher parasitic capacitance.

Accordingly, the present invention provides a method of manufacturing a self-aligned contact structure with lower parasitic capacitance to solve the above-mentioned problems.

### SUMMARY OF THE INVENTION

The present invention provides a method of manufacturing a self-aligned contact structure, in which an oxidation treatment is performed on a nitride spacer of the gate structure adjacent to the self-aligned contact, thereby manufacturing a self-aligned contact structure with lower parasitic capacitance.

The present invention also provides a method of manufacturing a self-aligned contact structure before the plug process, in which a nitride spacer surface is oxidized by using thermal treatment for the oxidation or the oxidant to reduce the dielectric constant.

To achieve the aforementioned objects, the present invention provides a method of manufacturing a self-aligned contact structure. A semiconductor substrate is provided having at least two gate stack structures and a dielectric layer formed thereon, wherein the dielectric layer covers the gate stack structures. Each gate stack structure has a nitride layer surface and a self-aligned contact via positioned between the gate stack structures. A portion of the dielectric layer is removed to expose a portion of the semiconductor substrate and the nitride layer surface. The exposed semiconductor substrate is positioned between two gate stack structures. A thermal oxidation is then performed on the nitride layer surface to reduce the dielectric constant of the nitride layer surface.

Therefore, while forming the subsequent self-aligned contact structure, the oxidized nitride layer surface is surrounded, thereby having exhibiting lower parasitic capacitance while operating the devices.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1a and FIG. 1b are sectional diagrams illustrating a method of manufacturing a self-aligned contact structure according to a preferred embodiment of the present invention; and

FIG. 2 is a data sheet with data illustrating using a thermal oxidation process to perform the oxidation on the nitride layer according to a preferred embodiment of the present invention.

### DETAILED DESCRIPTION OF THE PREFERRED EMBODIMENTS

While the present invention may be embodied in many different forms, there is shown in the drawings and discussed herein a few specific embodiments with the understanding that the present disclosure is to be considered only as an exemplification of the principles of the invention and is not intend to limit the invention to the embodiments illustrated.

The present invention provides a method of manufacturing a self-aligned contact structure on a semiconductor substrate, in which an oxidation treatment is performed on the exposed nitride layer surface to reduce the dielectric constant thereon. The oxidation treatment uses gases consisting of oxygen (O₂), water, nitrous oxide (N₂O), nitric oxide (NO), or deuterium oxide (D₂O), thereby performing the thermal oxidation. The UV O₃, the O₃ plasma, or an oxidant is used to perform the thermal annealing.

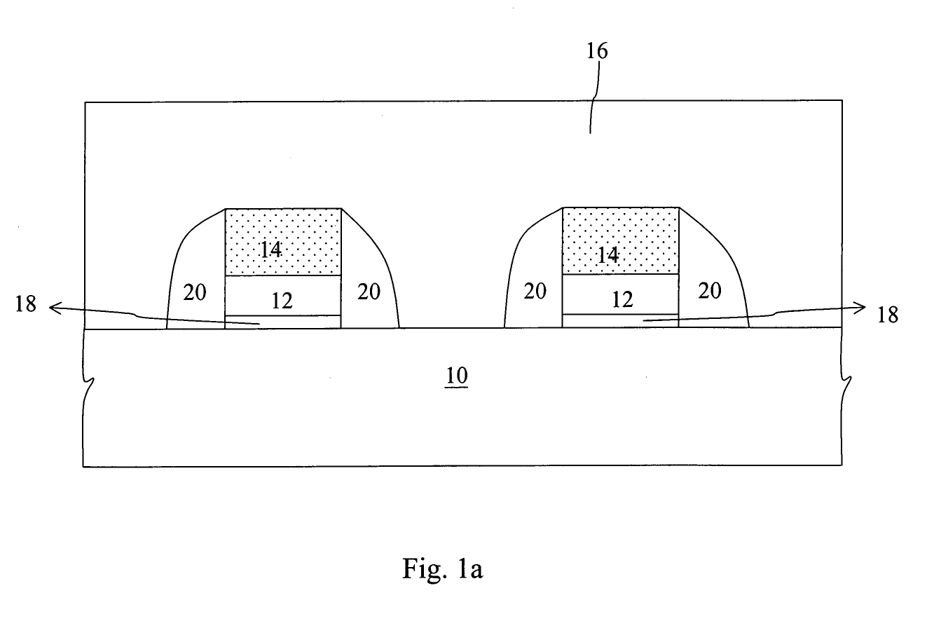

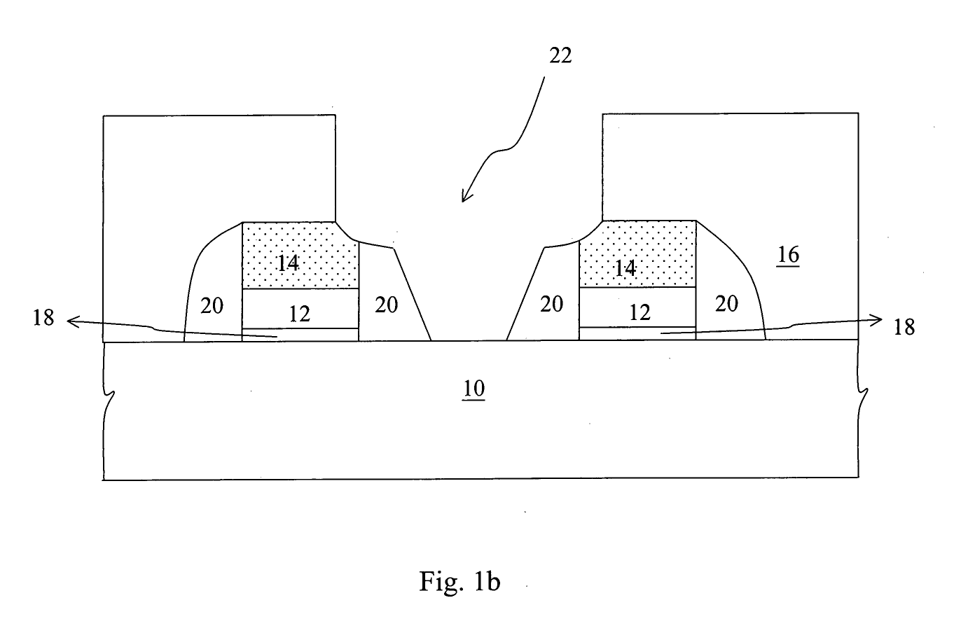

As shown in FIG. 1a, a plurality of gate stack structures is formed on a semiconductor substrate 10. Each gate stack structure has a pad oxide layer 18, a conductive electrode 12, an insulator 14, and an insulated spacer structure 20. A dielectric layer 16 is formed over the gate structures. A self-aligned via window is then formed between two gate stack structures and adjacent to the gate stack structures. The conductive electrode 12 is a single conductive layer of polysilicon or a stack structure of Oxide-Nitride-Oxide (ONO). The insulator 14 is regarded as a hard mask for protecting the conductive electrode 12 from improper etching during the subsequent process, for example, a nitride mask. The insulated spacer structure 20 is a double sidewall structure comprising a multi-insulator, for example, an oxide layer and a nitride layer. It should be noted that the most outer layer of the insulated spacer structure 20 is a nitride layer adjacent to the dielectric layer 16 no matter how the insulator is designed. In addition, the semiconductor substrate 10 comprises a plurality of implant areas, for example, lightly doped drain (LDD) region or the source/drain region. The dielectric layer 16 is an oxide layer used as an interlayer dielectric (ILD). The above-mentioned structures can be implemented by conventional processing.

Next, as shown in FIG. 1b, a portion of the dielectric layer 16 is removed to expose the surface of the semiconductor substrate 10 between two gate stack structures and to expose the nitride layer surface of the insulated spacer structure 20, thereby forming a space for a self-aligned contact 22. A portion of the insulator 14 is removed by this step. Before performing the plug process of the conductive contact, an oxidation treatment is performed on the nitride layer surface of the insulated spacer structure 20 surrounding the self-aligned contact 22, resulting in reducing the dielectric constant of the insulated spacer structure 20.

According to the present invention, the oxidation treatment is performed on the nitride layer surface of the insulated spacer structure 20 by using a thermal oxidation, or rapid thermal oxidation (RTO) is performed by using different gases, for example, oxygen (O₂), water, nitrous oxide (N₂O), nitric oxide (NO), or deuterium oxide (D₂O). In a preferred embodiment of the present invention, the temperature of the thermal oxidation is between 600° C. and 100° C., and the pressure is between 10 torrs and 760 torrs. In addition, an oxidant can be used to perform the oxidation treatment. The oxidant comprises UV O₃, O₃ plasma, oxygen ion implantation and annealing. After performing the oxidation treatment, the dielectric constant on the surface of nitride layer is reduced and the parasitic capacitance of the conductive contact formed subsequently is also reduced. Therefore, the method of the present invention provides a self-aligned contact structure with lower parasitic capacitance.

After completing the above-mentioned self-aligned contact and the subsequent oxidation treatment, a plug process is further performed to form the conductive contact structure.

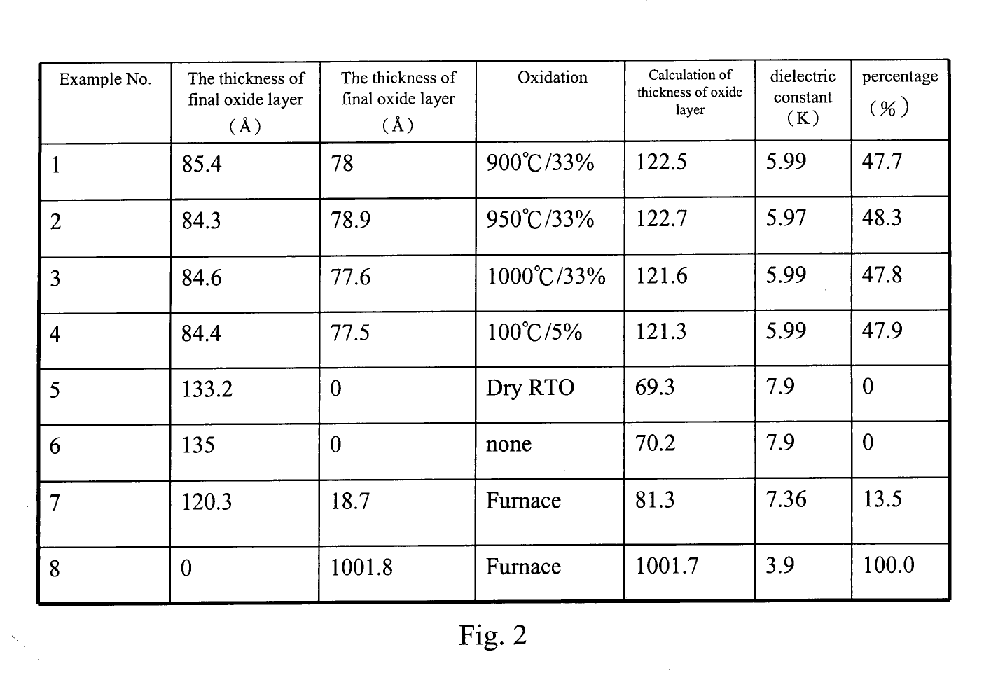

As shown in FIG. 2, which is a chart illustrating a data sheet using an In-Situ Steam Generation (ISSG) to perform the oxidation treatment on the nitride layer according to a preferred embodiment of the present invention. In example 8, the thickness of the final oxide layer is about 1001.8 Å, and the dielectric constant is about 3.9. In example 6, the spacer structure of the original nitride layer is 135 Å, and the equivalent thickness (ETO) of the nitride layer is 70.2 without performing the oxidation treatment, and the dielectric constant is 7.9. Any percentage is obtained by the calculation of the dielectric constant variation between the individual example and example 6, thereby discriminating the variation by the dielectric constant of single oxide layer. For example, example 1 is performed by an oxidation treatment at the temperature of 900° C. and a reaction gas containing 33%. The dielectric constant is 5.99. Compared with the nitride layer of example 6 without performing the oxidation treatment, example 1 has a reduction of 47.7% of the dielectric constant. As a result, the present invention provides a surface of nitride layer of spacer surrounding the self-aligned contact having a lower dielectric constant.

The embodiment above is only intended to illustrate the present invention; it does not, however, to limit the present invention to the specific embodiment. Accordingly, various modifications and changes may be made without departing from the spirit and scope of the present invention as described in the following claims.

What is claimed is:

1. A method of manufacturing a self-aligned contact structure, comprising:
providing a semiconductor substrate having at least two gate stack structures and a dielectric layer in sequence formed thereon, wherein the dielectric layer covers the gate stack structures, and wherein each gate stack structure has a nitride layer surface;
removing a portion of the dielectric layer to expose a portion of the semiconductor substrate and the nitride layer surface; and
performing an oxidation treatment on the nitride layer surface to reduce a dielectric constant of the nitride layer surface.

2. The method of manufacturing a self-aligned contact structure of claim 1, wherein each gate stack structure comprises:
a conductive electrode;
an insulator positioned on the conductive electrode; and
a spacer structure positioned on two sidewalls of the conductive electrode, wherein an outer surface of the spacer structure is a nitride surface.

3. The method of manufacturing a self-aligned contact structure of claim 2, further comprising forming spacer structures on two sidewalls of the insulator.

4. The method of manufacturing a self-aligned contact structure of claim 2, wherein the insulator is composed of a nitride layer.

5. The method of manufacturing a self-aligned contact structure of claim 1, wherein the oxidation treatment uses oxygen to perform a thermal oxidation.

6. The method of manufacturing a self-aligned contact structure of claim 1, wherein the oxidation treatment uses water to perform a thermal oxidation.

7. The method of manufacturing a self-aligned contact structure of claim 1, wherein the oxidation treatment uses nitrous oxide (N₂O) to perform a thermal oxidation.

8. The method of manufacturing a self-aligned contact structure of claim 1, wherein the oxidation treatment uses nitric oxide (NO) to perform a thermal oxidation.

9. The method of manufacturing a self-aligned contact structure of claim 1, wherein the oxidation treatment uses deuterium oxide (D₂O) to perform a thermal oxidation.

10. The method of manufacturing a self-aligned contact structure of claim 1, wherein the oxidation treatment uses UV O₃ ion implantation to perform a thermal oxidation.

11. The method of manufacturing a self-aligned contact structure of claim 1, wherein the oxidation treatment uses an O₃ plasma ion implantation to perform a thermal oxidation.

12. The method of manufacturing a self-aligned contact structure of claim 1, wherein the oxidation treatment uses an O₂ ion implantation to perform a thermal oxidation

13. A method of manufacturing a self-aligned contact structure, comprising a semiconductor substrate having two gate stack structures and a dielectric layer formed in sequence thereon, and wherein the dielectric layer covers the gate stack structures, and wherein each gate stack structure has a nitride layer surface, and a portion of the dielectric layer is removed to expose a portion of the semiconductor substrate and the nitride layer surface, characterized by:
performing an oxidation treatment on the nitride layer surface to reduce a dielectric constant of the nitride layer surface.

14. The method of manufacturing a self-aligned contact structure of claim 13, wherein the oxidation treatment uses oxygen to perform a thermal oxidation.

15. The method of manufacturing a self-aligned contact structure of claim 13, wherein the oxidation treatment uses water to perform a thermal oxidation.

16. The method of manufacturing a self-aligned contact structure of claim 13, wherein the oxidation treatment uses nitrous oxide (N₂O) to perform a thermal oxidation.

17. The method of manufacturing a self-aligned contact structure of claim 13, wherein the oxidation treatment uses nitric oxide (NO) to perform a thermal oxidation.

18. The method of manufacturing a self-aligned contact structure of claim 13, wherein the oxidation treatment uses deuterium oxide (D₂O) to perform a thermal oxidation.

19. The method of manufacturing a self-aligned contact structure of claim 13, wherein the oxidation treatment uses an oxidant ion implantation to perform a thermal oxidation.

20. The method of manufacturing a self-aligned contact structure of claim 13, wherein the oxidation treatment uses an oxidant annealing to perform a thermal oxidation.
